(19) United States
(12) Patent Application Publication
(10) Pub. No.: US 2005/0085053 A1
(43) Pub. Date: Apr. 21, 2005

(54) Method of activating a getter structure

(76) Inventors: Chien-Hua Chen, Corvallis, OR (US); James C. McKinnell, Salem, OR (US); John Liebeskind, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/689,821

(22) Filed: Oct. 20, 2003

(51) Int. Cl. H01L 21/322

(52) U.S. Cl. 438/471

(57) ABSTRACT

A method of activating a getter structure, including illuminating a photomask having a transmissive region substantially aligned with the getter structure, transmitting a portion of the photons through, the transmissive region. In addition the method includes absorbing the photons, transmitted through the transmissive region, in the getter structure and heating the getter structure with the absorbed photons.

### DESCRIPTION OF THE ART

The ability to maintain a controlled ambient condition for a prolonged period, such as a low pressure or vacuum, in a microelectronic package is increasingly being sought in such diverse areas as display technologies, micro-electro-mechanical systems (MEMS) and high density storage devices. Computers, displays, and personal digital assistants as well as cellular phones may all incorporate such devices utilizing a controlled ambient condition. Vacuum packaged devices may utilize electrons to traverse some gap, for example, to excite a phosphor in the case of displays, or to modify a medium to create bits in the case of storage devices.

One of the major problems with vacuum packaging of electronic devices is the continuous outgassing of hydrogen, water vapor, carbon monoxide, and other components found in air, and from the internal components of the electronic device. Typically, to minimize the effects of outgassing one uses gas-absorbing materials commonly referred to as getter materials. Generally a separate cartridge, ribbon, or pill incorporates the getter material that is then inserted into the electronic vacuum package. In addition, before the cartridge or cartridges are sealed within the vacuum package, in order to maintain a low pressure over the lifetime of the vacuum device, a sufficient amount of getter material must be contained within the cartridge or cartridges.

Providing an auxiliary compartment situated outside the main compartment is one alternative others have taken. The auxiliary compartment is connected to the main compartment such that the two compartments reach largely the same steady-state pressure. Although this approach provides an alternative to inserting a ribbon or cartridge inside the vacuum package, it still results in the undesired effect of producing either a thicker or a larger package. Such an approach, typically, leads to increased complexity, greater difficulty in assembly as well as generally a larger package size. For small electronic devices with narrow gaps, the bulkier package may be especially undesirable in many applications, such as those used in a mobile environment. In addition, the utilization of a separate compartment increases the cost of manufacturing because it is a separate part that requires accurate positioning, mounting, and securing to another component part to prevent it from coming loose and potentially damaging the device.

Depositing the getter material on a surface other than the actual device surface such as a package surface is another alternative approach taken by others. For example, a uniform vacuum may be produced by creating a uniform distribution of pores through the substrate of the device along with a uniform distribution of getter material deposited on a surface of the package. Although this approach provides an efficient means of obtaining a uniform vacuum within the vacuum package, it will also typically result in the undesired effect of producing a thicker package. The thicker package is required because of the need to maintain a reasonable gap between the bottom surface of the substrate and the top surface of the getter material to allow for reasonable pumping action. In addition, yields typically decrease due to the additional processing steps necessary to produce the uniform distribution of pores.

In all of these approaches, typically, either the entire packaged device is heated to the activation temperature of the getter material used, or electrical connections are provided to heat the getter material. In the former approach all of the components and materials utilized in the packaged device must be able to withstand the activation temperature of the getter material. In the latter approach, the additional electrical connections and electrical traces required to heat the getter material result in even more added complexity.

If these problems persist, the continued growth and advancements in the use electronic devices, in various electronic products, seen over the past several decades, will be reduced. In areas like consumer electronics, the demand for cheaper, smaller, more reliable, higher performance electronics constantly puts pressure on improving and optimizing performance of ever more complex and integrated devices. The ability, to optimize the gettering performance of getters may open up a wide variety of applications that are currently either impractical, or are not cost effective. As the demands for smaller and lower cost electronic devices continues to grow, the demand to minimize both the die size and the package size will continue to increase as well.

### BRIEF DESCRIPTION OF THE DRAWINGS

FIG. 1a is cross-sectional view of a device according to an embodiment of the present invention;

FIG. 1b is an expanded cross-sectional view of a photomask according to an alternate embodiment of the present invention;

FIG. 1c is an expanded cross-sectional view of a photomask according to an alternate embodiment of the present invention;

FIG. 1d is an expanded cross-sectional view of a photomask according to an alternate embodiment of the present invention;

FIG. 1e is an expanded cross-sectional view of a thermally isolated getter structure according to an alternate embodiment of the present invention;

FIG. 1f is an expanded cross-sectional view of a getter structure according to an alternate embodiment of the present invention;

FIG. 1g is an expanded cross-sectional view of a thermally isolated getter structure according to an alternate embodiment of the present invention;

FIG. 2a is a cross-sectional view of a device according to an alternate embodiment of the present invention;

FIG. 2b is an expanded cross-sectional view of a photomask according to an alternate embodiment of the present invention;

FIG. 3 is a flow diagram of a method of activating a getter structure according to an embodiment of the present invention;

FIG. 4a is a plan view of a photomask misaligned with a substrate having getter structures disposed thereon according to an embodiment of the present invention;

FIG. 4b is a plan view of the photomask shown in FIG. 4a after rotation having misalignment in some combination of X and Y;

FIG. 4c is a plan view of the photomask shown in FIG. 4b after movement in some combination of X and Y;

FIG. 5 is a cross-sectional view of a photomask according to an alternate embodiment of the present invention;

FIG. 6 is a cross-sectional view of a photomask according to an alternate embodiment of the present invention;

FIG. 7 is a flow diagram of a method of manufacturing a getter structure enclosed in a device package according to an embodiment of the present invention.

### DESCRIPTION OF THE PREFERRED EMBODIMENTS

The present embodiments of this invention are directed to devices utilizing a getter structure. For example, getter activation in a vacuum packaged device, typically, involves heating the entire device to a high temperature. Generally, a compromise is made between balancing the desire to heat the getter to a high temperature and the desire to maintain the viability of the semiconductor devices, all while maintaining the integrity of the vacuum seal or bond. Such a compromise is particularly desirable in those devices that include active semiconductor devices and activate the getter by heating the entire device. The present invention utilizes a photomask disposed between a photon source and the getter structure to selectively expose the getter structure to radiation while masking out areas having circuitry, other materials, or devices that are sensitive to high temperatures. In addition, thermal isolation structures such as a cavity formed under the getter structure, a serpentine structure, or a trench isolation structure surrounding the getter structure also may be incorporated into the vacuum device to further reduce the spread of heat out of the getter structure. In this manner a getter structure may be selectively activated to a high temperature while minimizing thermal degradation or damage to devices, materials, and other components that are in close proximity to the getter structure. Typically, the temperatures used to activate a getter such as a zirconium aluminum alloy are upwards of 900 to 1000° C. or for a zirconium vanadium iron alloy temperatures of 300 to 450° C.; these temperatures may be incompatible with circuitry such as various doped structures, or are incompatible with various polymeric materials or may cause delamination or cracking due to thermal expansion mismatches. The selective activation of a getter structure utilizing a photomask allows for increases in integration, improved functionality and lower cost.

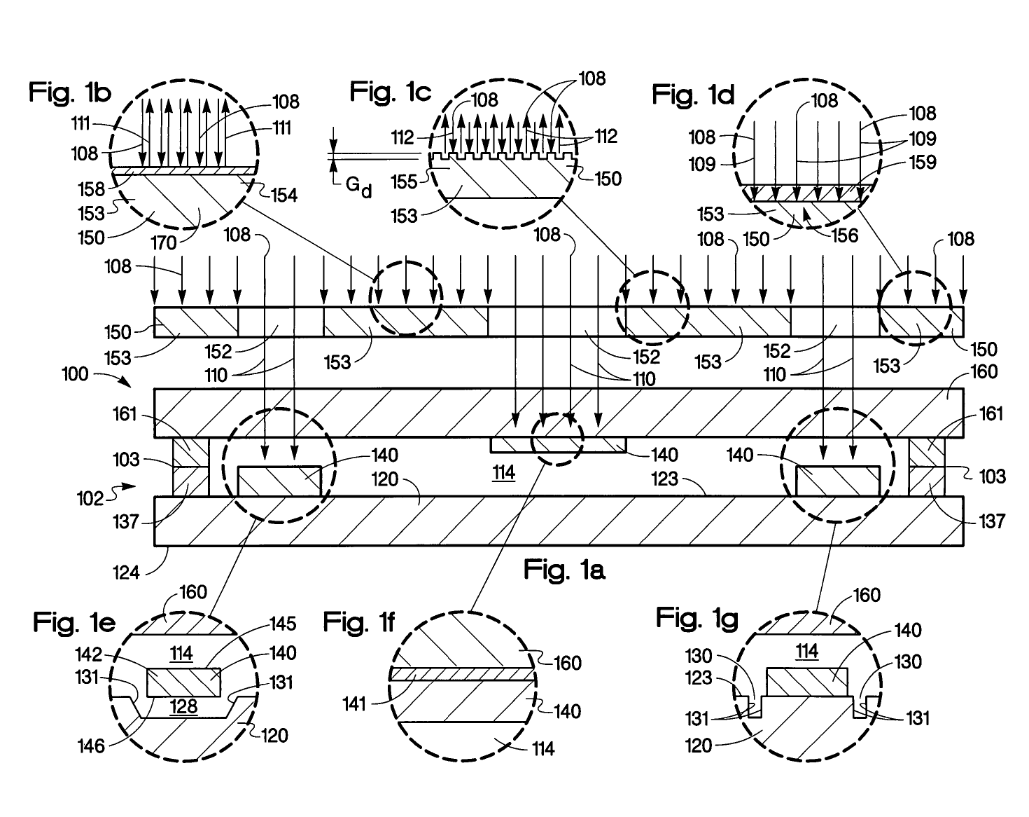

An embodiment of device 100 of the present invention, in a cross-sectional view, is shown in FIG. 1a. In this embodiment, getter structure 140 is utilized as a vacuum pump to maintain a vacuum or gas pressure below atmospheric pressure for device 100. Device 100 may be incorporated into any device utilizing a gas pressure less than atmospheric pressure, such as, electronic, MEMS, mechanical, and optical devices to name a few. In alternate embodiments, getter structure 140 may also be utilized to maintain the purity of a fluid (i.e. either a liquid or gas) in a device such as a micro-reactor, a fuel cell, or a microfluidic distribution network. As electronic manufacturers look for higher orders of integration to reduce product costs, typically, package sizes get smaller leaving less room for getter material. Electronic circuitry and devices disposed on a wafer or substrate limit the area available for getter structures. This limited area increases the desire to fabricate getters not only with high surface area structures having a small footprint on the substrate or wafer but also to fabricate getter structures on or near temperature sensitive devices, materials, or other components. In addition, in those embodiments utilizing wafer-level packaging, a technique that is becoming more popular for its low cost, placing a getter structure directly on the wafer in close proximity to other devices, both simplifies the fabrication process, as well as lowers the cost.

It should be noted that the drawings are not true to scale. Further, various elements have not been drawn to scale. Certain dimensions have been exaggerated in relation to other dimensions in order to provide a clearer illustration and understanding of the present invention.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by various embodiments, it is not intended that these illustrations be a limitation on the scope or applicability of the present invention. Further it is not intended that the embodiments of the present invention be limited to the physical structures illustrated. These structures are included to demonstrate the utility and application of the present invention in presently preferred embodiments.

In the embodiment shown in FIG. 1a, getter structure 140 is disposed on first major substrate surface 123 of substrate 120, with photomask 150 disposed over getter structure 140. In addition, getter structure 140 may also be disposed on sealing plate or package cover 160. Device 100, includes package 102 providing an enclosure in which the device may operate. The surface area and volume of the getter material included in getter structure 140 determines the getter pumping speed and capacity respectively of getter structure 140 after activation.

Photons emitted from a photon source (not shown) such as a laser impinge upon photomask 150. Any of a number of different photon sources may be utilized in the present invention. For example, various lasers such as semiconductor diode lasers, carbon dioxide lasers, ultraviolet lasers or neodymium YAG lasers all may be utilized. In addition, non-laser sources such as infrared lamps also may be utilized. Those photons (i.e. transmitted photons 110) incident on transmissive region 152 pass through photo mask 150 and impinge upon, and are absorbed by, getter structure 140. Those photons incident on non-transmissive region 153 are either reflected for those embodiments utilizing a reflective photomask, absorbed for those embodiments utilizing an absorbing photomask, or are destroyed by destructive interference or canceled for those embodiments utilizing a quarter wavelength dichroic filter or grating. In alternate embodiments, combinations of the various types of masks also may be combined and utilized in a single mask.

An example where photomask 150 includes reflective region 154 is illustrated in an expanded cross-sectional view in FIG. 1b. Incident photons 108 incident on transmissive region 152 (see FIG. 1a) are transmitted through photomask 150 whereas incident photons 108 incident on non-transmissive region 153 are reflected off the surface of reflective region 154 as represented by reflected photons 111 shown in FIG. 1b. Reflective region 154, in one embodiment, includes reflective film 158 formed or disposed on photomask substrate 170. The reflective photomask or the reflective film may be formed utilizing any material or system of layers providing sufficient reflectance to keep the temperature of temperature sensitive circuitry, materials, and devices below a desired value. For example, the reflective region 154 may utilize a thin metal film as reflective film 158, such as gold or aluminum deposited on a glass substrate. For those embodiments utilizing a photomask having only reflective regions in combination with transmissive regions the photomask may be formed utilizing, for example, a self supporting thin metal sheet having openings formed therein to form transmissive regions 152, or a non-self supporting sheet disposed and supported on a material having sufficient transmission in the energy region of the photons utilized to heat the getter structure. In addition, high-reflectance regions also may be formed utilizing multiple quarter wave dielectric layers that alternate between high and low refractive indices to form reflective layer 158. The refractive index at each interface goes from high to low for a light ray passing through the layers, phase reversal establishes constructive-interference providing in some optimized systems almost 100 percent reflectance at a particular wavelength. Such a coating may be utilized to form not only transmissive and non-transmissive regions but also regions having partial reflectance providing the ability to design temperature gradients and specified temperatures localized in both the getter structure and substrate being illuminated. By utilizing such a mask heating of the device and in particular the substrate may be controlled to provide a two dimensional temperature profile. In such a manner heating of the entire substrate or at least a substantial portion may be optimized at various discreet locations to provide substantial protection to the most sensitive areas and varying degrees of protection to other less sensitive areas. In addition, transmissive regions 152, for those embodiments utilizing a glass substrate for photomask 150, may also include antireflective coatings. For example, two quarter-wave layers of materials having refractive indices n₂ and n₃ will substantially reduce any surface reflectance at a given wavelength when n₃/n₂=(nₛ/nₐ)^{1/2} where nₛ is the index of refraction of the substrate and nₐ is the refractive index of air assuming the environment surrounding the photomask is air. Adding a third layer typically will broaden the range of wavelengths in which reflectivity is minimized. In addition, adding more layers increases the design alternatives.

An example where photomask 150 includes regions of destructive-interference 155 is illustrated, in an expanded cross-sectional view, in FIG. 1c. Incident photons 108 incident on transmissive region 152 (see FIG. 1a) are transmitted through photomask 150 whereas incident photons 108 incident on non-transmissive region 153 undergo destructive interference as shown in FIG. 1c. The grating period is less than the wavelength of the light incident on the grating. The depth of the grating G_{d} is an odd number of quarter wavelengths, of the light incident on the grating, divided by the index of refraction of the grating material. Such a mask controls both the amplitude and phase of the transmitted light. Those photons incident (i.e. incident photons 108) upon destructive interference regions 155 (i.e. grating photons 112 as illustrated in FIG. 1c) are canceled by interference effects due to both the grating structure and the index of refraction of the grating material which combine to change the phase of the alternating regions of the reflected photons by 180°. In this embodiment, photomask 150 may be formed from any material having sufficient transmittance in the wavelength region utilized by the incident photons to heat the getter structure. For example, photomask 150 may be a glass plate having the grating structure etched into the surface of the glass using conventional lithographic and etching techniques. For those embodiments utilizing infrared radiation to heat the getter structure photomask 150 also may be formed from a silicon plate or wafer. In addition, photomask 150 also may be formed in a plastic substrate such as polycarbonate, polymethylmethacrylate or other polymer material having the appropriate optical properties for a quarter wavelength grating. Such a plastic grating may be formed utilizing lithography and etching or alternatively such a grating may be formed utilizing, for example, micromolding techniques.

An example where photomask 150 includes absorptive regions 156 is illustrated in an expanded cross-sectional view in FIG. 1d. Incident photons 108 incident on transmissive region 152 are transmitted through photomask 150 (see FIG. 1a) whereas incident photons 108 incident on non-transmissive region 153 or absorptive region 156 that includes absorptive layer 159 are absorbed. Absorptive layer 159 may be formed utilizing any material having sufficient absorptive properties for the wavelength region utilized to heat the getter structure while keeping the temperature of temperature sensitive circuitry, materials, and devices below a desired value. For example, absorptive region 156 may utilize a thin ceramic film as absorptive layer 159, such as aluminum oxide, boron nitride, or silicon carbide deposited on a glass substrate. In alternate embodiments, a ceramic mask having laser ablated or etched transmissive regions also may be utilized. In still other embodiments, a carbon layer formed on a glass photomask substrate or a metal sheet or metal film having a substantially rough surface limiting reflection also may be utilized. It should be appreciated that photomask 150 may utilize any of the various photomasking techniques utilized in a wide range of applications. The particular material and type of photomask utilized in the present invention will depend on various factors such as the size and shape of the getter structure or structures to be heated, the substrate material over which or on which the getter structure is formed, the particular photon source utilized, and whether the photomask is formed on a device package component or positioned above or a distance away from the device package. In addition, photomask 150 may be any suitable type of photomask such as contact, proximity, projection scanning, and projection step-and-repeat masking techniques, or other suitable lithographic masking technique.

Substrate 120, in this embodiment, is an aluminum oxide substrate; however, substrate 120 may be formed from a wide range of materials including ceramics, metals, various semiconductor materials such as silicon, gallium arsenide, indium phosphide, germanium; various glasses such as any of the borosilicate, soda lime or quartz glasses (including crystalline and amorphous glasses) as well as silicon oxides, nitrides, and silica mixed with oxides of, for example, potassium, calcium, barium or lead; other various ceramics such as boron nitride, silicon carbide, and sapphire. In this embodiment substrate 120 may be any suitable material including polymeric materials having the desired thermal properties to withstand the activation temperature of getter structure 140 without suffering substantial degradation or damage.

Sealed package 102, in this embodiment includes a vacuum seal formed between sealing plate 160 and substrate 120. In alternate embodiments, sealed package 102 may be formed, for example, between a package cover and a chip carrier on which a chip or chips are mounted, or between two chip carriers each having a chip or chips mounted thereto. Any packaging arrangement providing a controlled environment for device 100 to operate in may be utilized in the present invention. For example, a vacuum package forming a vacuum environment in which electron emitters may be utilized for displays and storage devices. Another example is the use of a vacuum environment to reduce gas viscosity damping of a mechanical resonator. In still other embodiments, sealed package 102 also may be an enclosure providing fluid flow for other applications such as, for example, micro turbines, fuel cells, chemical reactors, and catalytic fuel crackers. Further, sealed package may provide an enclosure to hold a particular gas or liquid such as a micro-mirror display or other micro-mover device.

Substrate bond structure 137 is disposed on substrate 120. Depending on the particular sealing technology utilized, substrate bond structure 137 may be formed on substrate 120 directly or it may be formed on a compatible layer or film that is formed on substrate 120. Sealing plate bond structure 161 is disposed on sealing plate 160. Again depending on the particular sealing technology utilized, Sealing plate bond structure 161 may be formed on sealing plate 160 directly or it may be formed on a compatible layer or film that is formed on sealing plate 161. Sealing plate bond structure 161 and substrate bond structure 137 form package seal 103 forming interspace region 114. In this embodiment, substrate bond structures 137 and sealing plate bond structures 161 may utilize a wide variety of materials depending on the particular sealing technology utilized. For example, a gold-silicon eutectic for bonding may be utilized to bond substrate 120 to sealing plate 160 if substrate 120 is a silicon substrate. A softer lower melting-point solder also may be utilized if substrate 120 is, for example, a silicon, glass, or other inorganic material. In alternate embodiments, a frit glass seal may be utilized to form sealed package 102. In still other embodiments, package seal 103 may be made by a variety of techniques such as, for example, thermal compression bonding or brazing, as well as other techniques.

The material utilized for the bond structures will depend on the particular materials utilized for substrate 120, and sealing plate 160. In those embodiments utilizing a chip carrier, various ceramic materials including various glasses as well as metals may be utilized to form one or both of the carriers, however, at least one carrier should either be transmissive to the photon energy utilized to activate the getter structure or structures, or have transmissive regions aligned with the getter structure or structures formed in at least one carrier. The particular material utilized to form both a carrier as well as the bond structures will depend on, for example, the desired pressure to be maintained; the temperature and humidity and other environmental factors to which the device will be exposed; and the amount of stress that may be imparted to the device as a result of the packaging process; as well as, the particular sealing technology to be utilized.

Anodic bonding may be utilized to attach device 100 made on a silicon substrate to the sealing plate either made out of glass or having a glass surface to bond to the silicon. The silicon surface of the substrate and, for example, the glass surface of the sealing plate are placed between two electrodes applying an appropriate polarity voltage across the interface of the two materials. The particular bonding process will depend on various parameters such as the magnitude and duration of the applied voltage, the temperature of the two surfaces during the bonding process, and the area to be bonded. Getter material may also be applied or deposited on various portions of sealing plate 160 (as shown in FIG. 1a) to provide further gettering action within sealed package 102 during operation of device 100.

An alternate embodiment of a getter structure utilized in a device of the present invention is shown, in a cross-sectional view, in FIG. 1e. In this embodiment, getter structure 140 includes free standing or suspended mass portion 142 and a thermally coupled portion (not shown), that is thermally coupled to substrate 120. Suspended mass portion 142 is suspended over cavity 128 formed in substrate 120 and includes sidewalls 131. In this embodiment, sidewalls 131 are depicted as having sloping sidewalls extending from first major substrate surface 123 to the bottom of cavity 128; however, in alternate embodiments straight vertical, or orthogonal sidewalls or other more complex structures also may be utilized.

Getter structure 140 includes first major getter surface 145 facing away from first major substrate surface 123 and second major getter surface 146 facing toward first major substrate surface 123. Cavity 128 provides a path for molecules or atoms to impinge upon both first and second major getter surfaces 145 and 146 of getter structure 140, thus, increasing the exposed surface area available for pumping residual molecules or atoms. The increased surface area provides an increase in the effective pumping speed of getter structure 140. In addition, cavity 128 also provides thermal isolation of getter structure 140 from substrate 120. Heat generated within getter structure 140, typically, may be lost through radiation, convection, or through thermal conduction along the length of suspended mass portion 142 to the thermally coupled portion. In this embodiment, getter structure 140 is illustrated in FIG. 1e as a single layer structure, however, in alternate embodiments getter structure 140 may include multiple getter layers stacked upon each other with a gap formed between the getter layers. Such a structure provides a further increase in exposed surface area and a corresponding further increase in the effective pumping speed of the getter structure. In still other embodiments, getter structure 140 also may be disposed on any other layer or layers, formed on the substrate, that have sufficient thermal stability to withstand the temperatures desired for activation of getter structure 140.

An alternate embodiment of a getter structure utilized in a device of the present invention is shown, in a cross-sectional view, in FIG. 1f. In this embodiment, getter structure 140 includes absorption layer 141 disposed between sealing plate 160 and getter structure 140 as shown, in an expanded view, in FIG. 1f. Absorption layer 141 provides increased localized absorption of radiation incident upon getter structure 140, and may also provide increased adhesion of getter structure 140 to the sealing plate. For example, if the sealing plate is a glass substrate then absorption layer 141 may be a thin chromium, titanium, vanadium layer, or other suitable metal layer. Any suitable adhesion promoting material having the desired photon absorption, adhesion, and thermal properties for the particular sealing plate and getter material used may be utilized for absorption layer 141.

An alternate embodiment of a getter structure utilized in a device of the present invention is shown, in a cross-sectional view, in FIG. 1g. In this embodiment, getter structure 140 is disposed on first major substrate surface 123 of substrate 120. Trench 130 is formed in substrate 120 to a predetermined depth. The particular depth utilized will depend on various factors such as the activation temperature of the getter material utilized in the getter structure, the thermal conductivity of the substrate, the temperature sensitivity of surrounding devices, circuitry, and materials. In this embodiment, sidewalls 131 of trench 130 are depicted as having straight vertical or orthogonal sidewalls to the bottom of trench 130, however, in alternate embodiments sloping sidewalls or other more complex structures also may be utilized. In still other embodiments, a cavity also may be formed under getter structure 140 with an opening formed in one or more of the sidewalls in trench 130, including a cavity leaving only posts or support structures in, for example, the corners of getter structure 140. It should be appreciated that multiple combinations of the embodiments shown in FIGS. 1a-1g also may be utilized in a particular device.

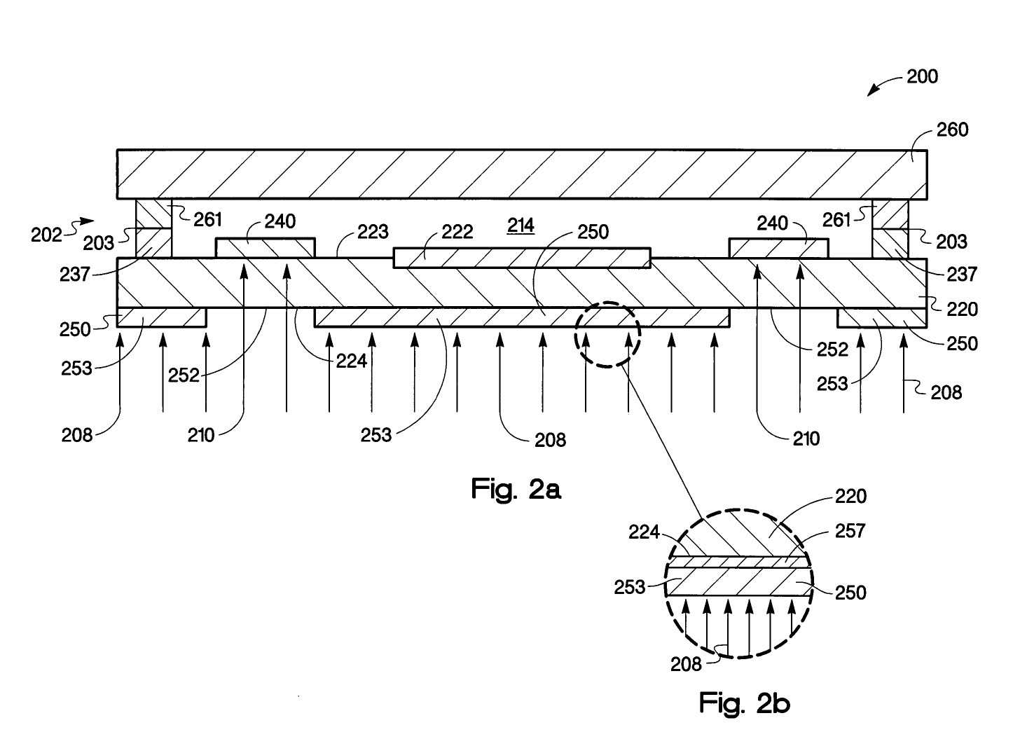

An alternate embodiment of the present invention is shown in FIG. 2a, in a cross-sectional schematic view. In this embodiment, getter structure 240 is disposed on first major substrate surface 223 of substrate 220 with photomask 250 disposed on second major substrate surface 224 of substrate 220. Photons emitted from a photon source (not shown) such as a laser impinge upon photomask 250. Those photons incident on transmissive region 252 pass through photomask 250 and impinge upon second major substrate surface 224 of substrate 220. These photons are then transmitted through substrate 220 and impinge upon, and are absorbed by, getter structure 240. In addition, device 200 also includes active device 222 disposed on first major substrate surface 223 of substrate 220. Active device 222 includes, for example, various transistors (including thin-film-transistor (TFT) technology using polysilicon on glass substrates), diodes, logic cells, or passive components such as capacitors and resistors as well as sensors, transducers, electron emitters, bolometers, and superconductoring high Q RF filters to name just a few of the many active devices that may be utilized in the present invention either separately or in combination. In alternate embodiments, active device 222 may also be integrated with various MEMS devices such as microfluidic channels, reactor chambers, micromovers, and actuators to name just a few of the many MEMS devices that may be utilized. For example, device 200 may include a micro mirror disposed on device substrate 220 including a reflective surface disposed on said mirror. Another example is a bolometer or other radiation detector having a light absorbing surface disposed on said device substrate. To simplify the drawing active device 222 is represented as only a single layer in FIG. 2a although it is readily apparent that such devices typically may be realized as a stack of thin film layers.

Substrate 220, in this embodiment, is a mono-crystalline silicon substrate; however, any substrate suitable for forming electronic devices, such as germanium, zinc selenide, silicon carbide, gallium arsenide, indium phosphide, glass, and sapphire are a just a few examples that also may be utilized. In addition materials such as magnesium fluoride, and cryolite, and various glasses such as any of the borosilicate, soda lime or quartz glasses (including crystalline and amorphous glasses) as well as silicon oxides, and silica mixed with oxides of, for example, potassium, calcium, barium or lead also may be utilized. For those embodiments where the photons used to activate the getter structure are transmitted through the substrate, the substrate may include any suitable material having sufficient transmittance in the wavelength region of photons utilized to provide sufficient heat to activate the getter structure as well as having thermal properties sufficient to withstand the activation of the getter structure without suffering substantial degradation or damage. The present invention is not intended to be limited to those devices fabricated in silicon semiconductor materials, but will include those devices fabricated in one or more of the available semiconductor materials and technologies known in the art, such as thin-film-transistor (TFT) technology using polysilicon on glass substrates. Further, the substrate is not restricted to typical wafer sizes, and may include processing a sheet or film, for example, a single crystal sheet or a substrate handled in a different form and size than that of conventional wafers or substrates. The actual substrate material utilized will depend on various system components such as the particular environment to which the device will be subjected, the presence or absence of active devices, the pressure to be maintained within the device, as well as the expected lifetime of the device.

Examples of getter materials that may be utilized in the present invention include zirconium, thorium, hafnium, vanadium, yttrium, niobium, tantalum, molybdenum, terbium, and mixtures thereof. In the embodiments shown in FIGS. 1a and 1b, the getter material is a zirconium-based alloy such as Zr—Al, Zr—V, Zr—V—Ti, or Zr—V—Fe alloys. However, in alternate embodiments, any material having sufficient gettering capacity for the particular application in which a device of the present invention will be utilized also may be used. For example, zeolites may be utilized to selectively adsorb various molecules such as water, carbon dioxide, ammonia and other organic compounds in a micro-reactor, a catalytic fuel cracker, a fuel cell, or a microfluidic distribution network. In still other embodiments, various reactive metals or organic compounds that selectively adsorb or absorb an unwanted impurity may be utilized. Getter structure 140 may be formed utilizing a wide range of techniques. For example, the zirconium alloys described above may be deposited using conventional sputtering or vapor deposition equipment, however, in alternate embodiments, other deposition techniques such as electroplating, or laser activated deposition also may be utilized. In still other embodiments, sintering, solvent casting, spin coating, and dip coating are just a few examples of techniques that also may be utilized.

In this embodiment, any of the photon sources described above that emit in the infrared region of the electromagnetic spectrum from about 1.2 micrometer in wavelength to about 10 micrometers in wavelength such as a carbon dioxide laser or solid state lasers may be utilized. Photomask 250, in this embodiment, may be any of the photomasks described above. For example, photomask 250 may be a reflective type mask such as gold or aluminum deposited on second major substrate surface 224 of substrate 220; however, in alternate embodiments photomask 250 may be disposed on any other layer or layers, formed on the substrate. In still other embodiments, as illustrated in the expanded cross-sectional view shown in FIG. 2b, mask release layer 257 may be disposed between photomask 250 and substrate 220. Mask release layer 257 may be any layer providing sufficient adhesion of photomask 250 to substrate 220 while providing controlled release of the photomask from the substrate after the getter structure has been activated. For example, mask release layer 255 may be a metal or dielectric film that is more rapidly etched than the substrate and photomask materials. Another example is the use of a polymer film such as polyvinyl alcohol that is water soluble or polymers such as polycarbonate or polyacrylates that are solvent soluble. Pressure sensitive adhesives, or other adhesives also may be utilized.

Sealed package 202, in this embodiment includes a seal formed between package component 260 and substrate 220. Substrate bond structure 237 is disposed on substrate 220 and package bond structure 261 is disposed on package component 260. Package bond structure 261 and substrate bond structure 237 form package seal 203 forming interspace region 214. This embodiment may utilized any of the package sealing structures, materials and techniques described above in FIG. 1a.

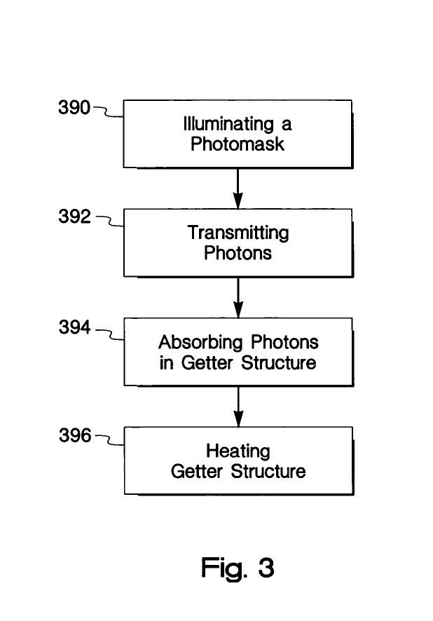

A flow diagram of a method of activating a getter structure enclosed in a device package, according to an embodiment of the present invention, is shown in FIG. 3. Photomask illuminating process 390 is utilized to provide uniform illumination over at least a region of the photomask, and depends on the particular photon source and exposure tool used to activate the getter structure. Any of a number of different photon sources may be utilized in the present invention. For example, various lasers such as semiconductor diode lasers, carbon dioxide lasers, ultraviolet lasers or neodymium YAG may all be utilized. In addition, non-laser sources such as infrared lamps also may be utilized. Generally, the region of the photomask illuminated will be larger than the transmissive region or regions of the photomask, and may include illumination over a substantial portion of the photomask for those embodiments utilizing a full-field mask. For example, for those embodiments utilizing a photomask disposed on or deposited on a package surface the photons emitted from the photon source are collimated typically utilizing various types of lens systems. For those embodiments utilizing a photomask disposed away from the device package various projection systems such as scanning projection systems or step and repeat systems may be utilized. Such systems typically use complex lens systems to focus the mask image onto the device and more specifically the getter structure. Both reflective and refractive lens systems may be utilized. In a scanning projection system typically both the mask and device are mechanically scanned utilizing a single carriage that carries the mask and device through an illuminated zone of good correction to reduce aberrations of the optical system.

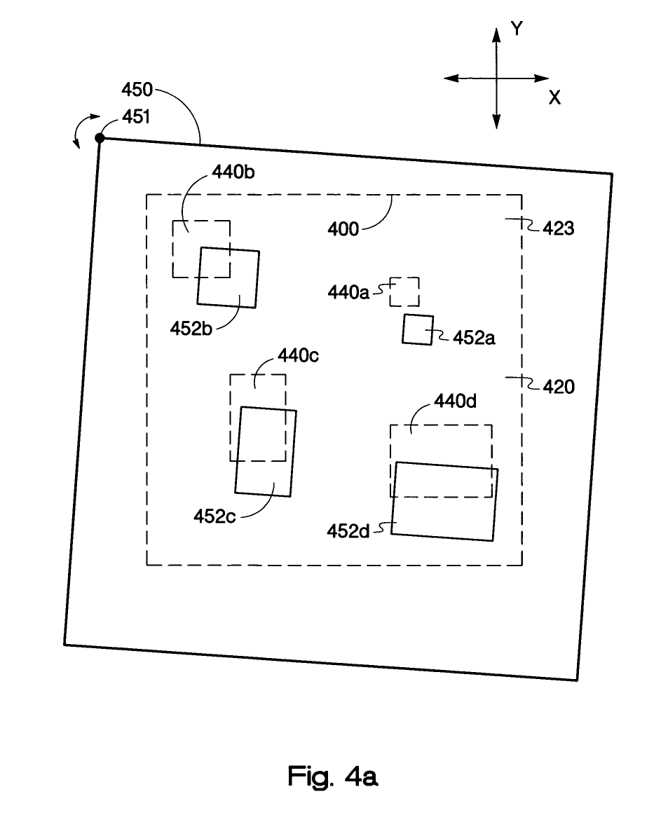

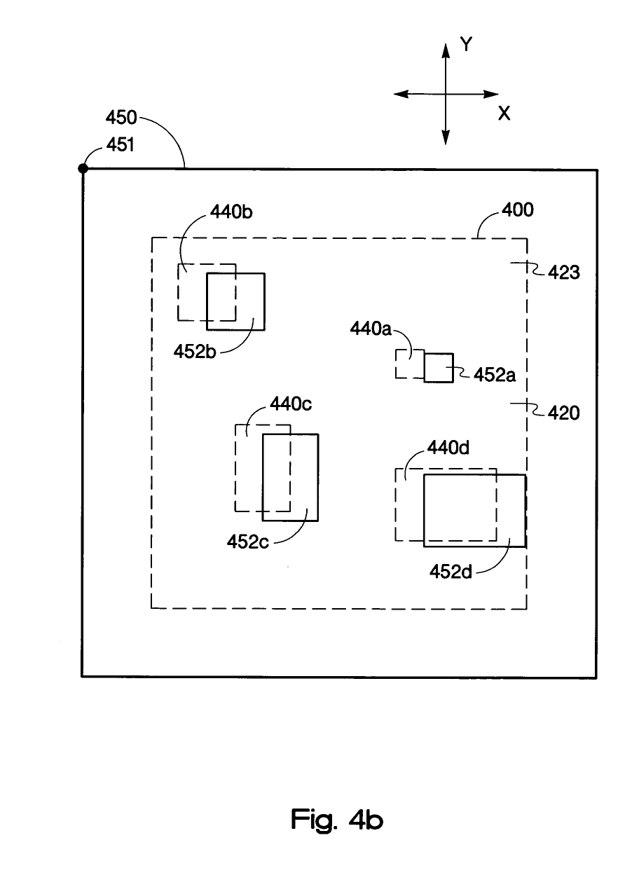

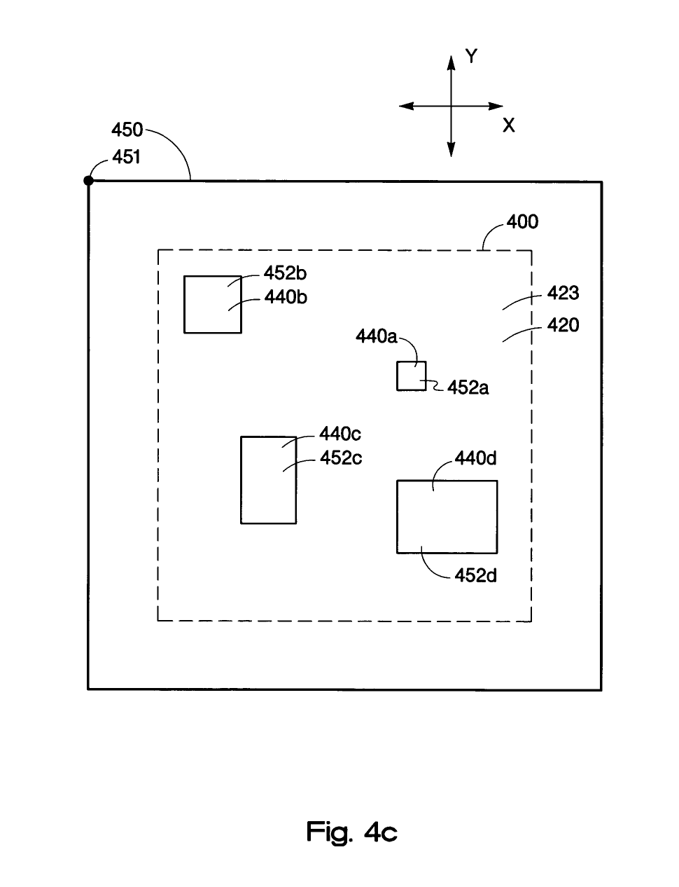

For those embodiments utilizing a photomask disposed away from the device package photomask illuminating process 390 also may utilize a positioning process as illustrated, in a plan view, in FIGS. 4a-4c. For illustrative purposes only four getter structures 440a, 440b, 440c, and 440d are disposed on substrate 420 of device 400 as shown in FIGS. 4a-4c. Photomask 450 includes four transmissive regions 452a, 452b, 452c, and 452d. As illustrated in FIG. 4a with getter structure 440a and transmissive region 452a if there is substantial misalignment of the photomask to the substrate then illumination of the photomask may lead to heating of the substrate in areas where temperature sensitive circuitry, materials or other devices may be located. The greater the misalignment the greater the potential for degradation or damage. Heating in these areas may lead to degradation or damage of the device. Although the particular alignment process utilized will depend on the particular photo tool used, typically, either the mask or the device is moved in two mutually orthogonal directions. In addition, rotation about photomask rotation axis 451 shown in FIGS. 4a-4c, also may be utilized to reduce or limit any rotational misalignment between the photomask and the device, as illustrated in going from FIG. 4a having rotational misalignment, to FIG. 4b where the rotational misalignment has been corrected.

The rotation about axis 451 is for illustrative purposes only; any suitable axis of rotation of photomask 450 may be utilized. In addition, any suitable axis of rotation of device 400 also may be utilized where device 400 is rotated with respect to photomask 450. Movement in some combination of X and Y may be utilized to reduce or limit any misalignment in the plane formed by the two mutually orthogonal directions as illustrated in going from FIG. 4b having both X and Y misalignment to FIG. 4c where the transmissive regions 452a, 452b, 452c, and 452d are aligned with the getter structures 440a, 440b, 440c, and 440d. In addition, other categories of misalignment also may be corrected and will depend on the particular photo tool being utilized. For example, in some phototools such as projection systems the photomask or device may be adjusted to be a specified distance from the getter structure to obtain the desired focussed image of the transmissive regions in the photomask on the getter structure surface. In still other embodiments, tilt of the photomask relative to the substrate also may be corrected. For those embodiments utilizing a photomask disposed on or deposited on a package surface the alignment process is generally performed during formation of the photomask itself. For example, for those embodiments utilizing a photomask deposited onto the opposing surface or backside of the substrate conventional patterning techniques may be utilized to align the transmissive regions with the getter structures. For those embodiments utilizing a photo mask separately formed and later attached or mounted to a package surface alignment may be performed before or during the attachment process. And for those embodiments utilizing a photomask formed on or attached to a package lid or cover alignment may be performed during formation or attachment with a subsequent final alignment performed during the package sealing process.

Photon transmission process 392 is utilized to provide selective illumination of a getter structure. Illumination of a photomask utilizing both transmissive and non-transmissive regions provides for selectively exposing the getter structure to radiation via transmission of photons through the transmissive region while masking out or preventing transmission of photons in areas having circuitry, other materials, or devices that are sensitive to high temperatures. In this manner, by reducing or limiting the temperature excursion experienced in more sensitive regions, a getter structure may be selectively heated to a high temperature while minimizing thermal degradation or damage to devices, materials, and other components that are in close proximity to the getter structure. Generally, the temperatures used to activate a getter such as a zirconium aluminum alloy are upwards of 900 to 1000° C. For a zirconium vanadium iron alloy temperatures of 300 to 450° C. may be used. Such temperatures may be incompatible with circuitry such as various doped structures, or may be incompatible with various polymeric materials or may cause delamination or cracking due to thermal expansion mismatches. The localized heating of the getter structure in the present invention reduces or may eliminate these problems.

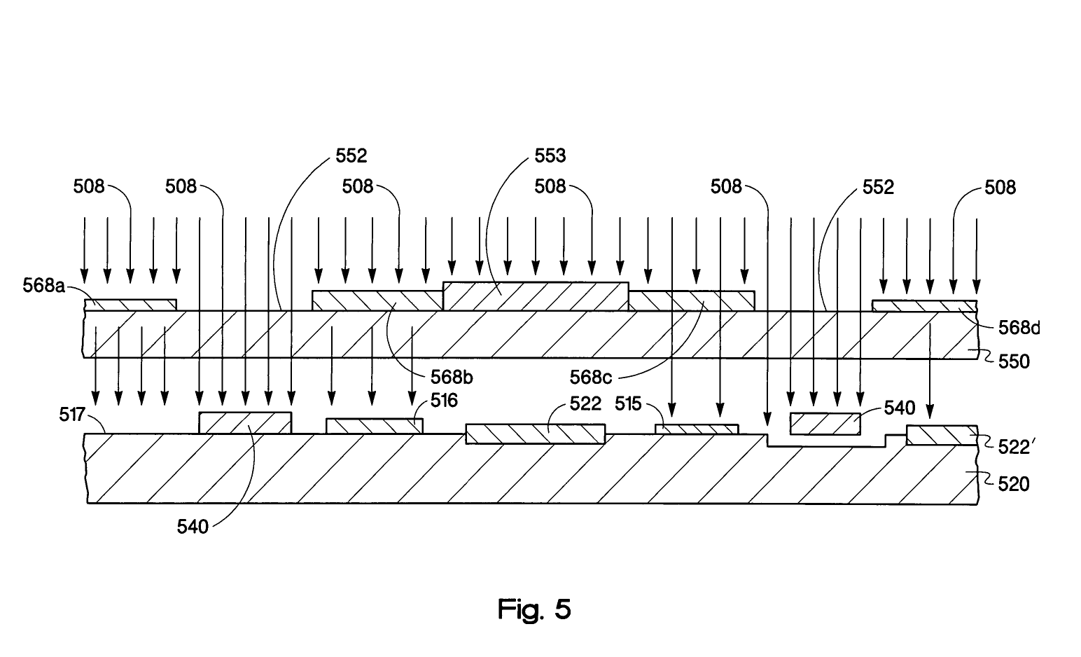

Those photons incident on a transmissive region pass through the photo mask and impinge upon a getter structure. Photons incident on a non-transmissive region are not transmitted through the photomask and do not contribute to heating either the substrate or the getter structure as illustrated in FIGS. 1 and 2. Any of the photomasks in the embodiments described in FIGS. 1 and 2 may be utilized. For example, a reflective mask formed from a metal sheet utilizing openings in the sheet to form the transmissive regions may be utilized or a thin metal film such as gold or aluminum deposited on a glass substrate with the transmissive regions formed utilizing conventional patterning or lithography techniques. In addition, for those photomasks utilizing a substrate on which various layers are formed or deposited the photomask may also utilize antireflective coatings formed in the transmissive regions of the mask. Further, photomasks having reflective, partially reflective and non-reflective regions may also be utilized as illustrated in a cross-sectional view in FIG. 5. For illustrative purposes only substrate 520 includes, besides getter structures 540, a number of representative regions having various circuitry, materials, and devices that have varying degrees of temperature sensitivity. For example, regions 522 and 522′ may include shallow junction devices or semiconductor devices utilizing organic or polymeric materials and, in this illustration, represent the most temperature sensitive regions with region 522 being more susceptible to temperature than 522′. Region 515 represents the next most sensitive region. Region 517 is the least sensitive with region 516 being between 517 and 515 in temperature sensitivity. Transmissive regions 552 are formed in photomask 550 providing substantial transmission of incident photons 508. Generally transmissive regions 552 will have transmissivities greater than 90 percent and those utilizing either antireflective coatings or openings formed in the mask substrate may approach 100 percent transmission. Non-transmissive regions are represented by structure 553 for illustrative purposes only and may be a metal reflective film or multiple quarter wave dielectric layers that alternate between high and low refractive indices to form a reflective layer as described earlier. Generally non-transmissive regions 553 will have transmissivities of less than a few percent and typically approaching zero percent transmission. Partial transmissive regions 568a, 568b, 568c, and 568d provide varying degrees of transmission of incident photons 508 to heat temperature sensitive regions 517, 516, 515, and 522′ respectively to various desired temperatures. For illustrative purposes only partial transmissive region 568a, in the figure, represents 80 percent transmission while regions 568b, 568c, and 568d represent 60, 40 and 20 percent transmission respectively. It should be appreciated that the percent transmission may be varied continuously over the entire range from 99.9 percent to zero percent. For those embodiments utilizing a vacuum device such a combination of transmissive, partially transmissive, and non-transmissive regions formed in a photomask allows one to select the degree of outgassing to which various portions of the device will be subjected.

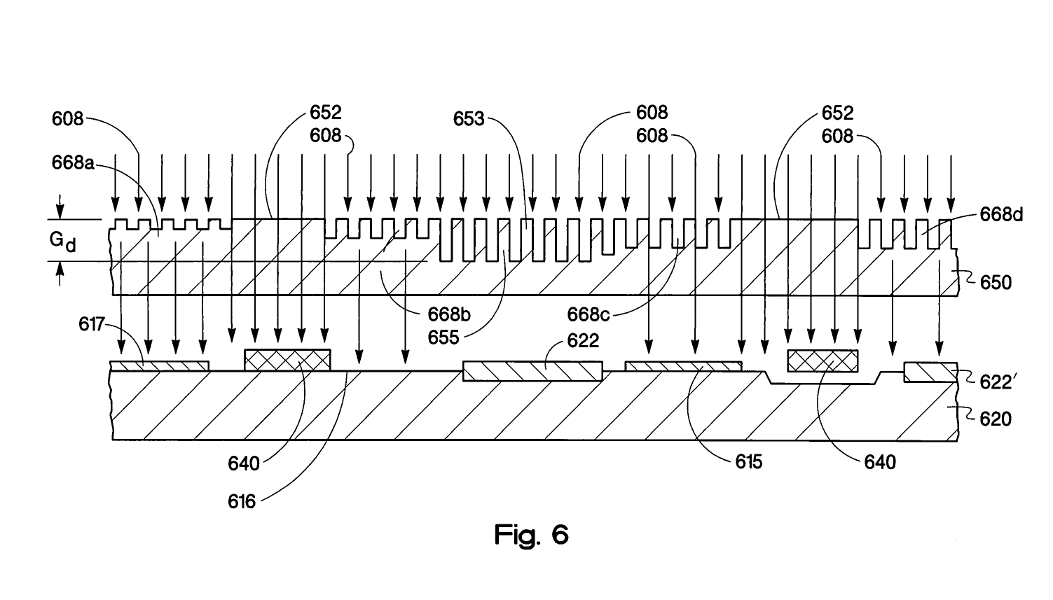

For those embodiments utilizing a grating mask or a mask having absorption regions with similar partially transmissive regions may be formed in the mask to provide selective heating of various portions of the substrate. An example of such a grating mask is illustrated in FIG. 6. As described above for the reflective mask having partially transmissive regions shown in FIG. 5, besides getter structures 640, substrate 620 includes a number of representative regions having various circuitry, materials, and devices that have varying degrees of temperature sensitivity. Partial transmission regions 622′, 617, 616, and 615 are illustrated as simple regions and are not indicative of any particular structure or device as described above in FIG. 5. In this embodiment, photomask 650 includes transmissive regions 652 having transmissivities greater than 90 percent with those utilizing either antireflective coatings or openings formed in the mask substrate may approach 100 percent transmission. In addition, photomask also includes non-transmissive regions 653 represented by destructive interference region 655 where incident photons 608 undergo destructive interference as the photons are reflected from photomask 650. The grating period is less than the wavelength of the light incident on the grating. To satisfy the condition for destructive interference the depth of the grating G_{d} is an odd number of quarter wavelengths, of the light incident on the grating, divided by the index of refraction of the grating material as illustrated in FIG. 6. Such a mask controls both the amplitude and phase of the transmitted light. Partial transmissive regions 668a, 668b, 668c, and 668d include grating structures that produce varying degrees of destructive interference by varying the depth of the grating structure formed in photomask 650. By varying the depth from an odd number of quarter wavelengths to the flat surface illustrated in transmissive region 652 the amount of transmission in various regions may be varied in a similar manner as that described above for the reflective photomask. In addition, layers having various indexes of refraction also may be utilized to further vary the degree of destructive interference.

Photon absorbing process 394 is utilized to selectively provide heat to a getter structure. After transmission through the transmissive regions of the photomask the incident photons will either pass through the substrate, or the sealing plate, or other structure depending on the particular arrangement utilized, and impinge on the getter structure where they are absorbed. Generally the getter material utilized to form the getter structure will have a high absorption coefficient, however in those embodiments where additional absorption is desired an absorption layer also may be utilized as illustrated in FIG. 1f. Although FIG. 1f depicts the incident photons impinging directly on the absorption layer it should be appreciated that the incident photons may impinge directly on the getter structure as illustrated in FIGS. 1e and 1g where those photons not absorbed by the getter structure are then absorbed in the absorption layer.

Getter structure heating process 396 is utilized to selectively heat a getter structure to its activation temperature and will depend on the particular getter material utilized. For example, a zirconium aluminum alloy may be activated at temperatures in the range from about 900° C. to about 1000° C. For a zirconium vanadium iron alloy temperatures from about 300° C. to about 450° C. may be used. Zeolites may be activated by heating to temperatures from about 100° C. to about 300° C. In addition, the activation of a getter material is generally temperature time dependent. The lower the temperature used to activate the getter the longer the getter material is held at that temperature. The particular activation temperature utilized will depend not only on the getter material used, but also on other factors such as the substrate material (in particular the thermal conductivity of the substrate) used, the presence or absence of temperature sensitive circuitry, materials, or devices in the vicinity of the getter structure, and the presence or absence of thermal isolation structures utilized with the getter structure. The longer the getter structure is heated the greater will be the heat load to other parts of the device due to thermal conduction, radiation, and convection. In addition, getter structure heating process 396 may also include reactivating the getter structure at a specified pressure or after or at a specified time from the previous activation.

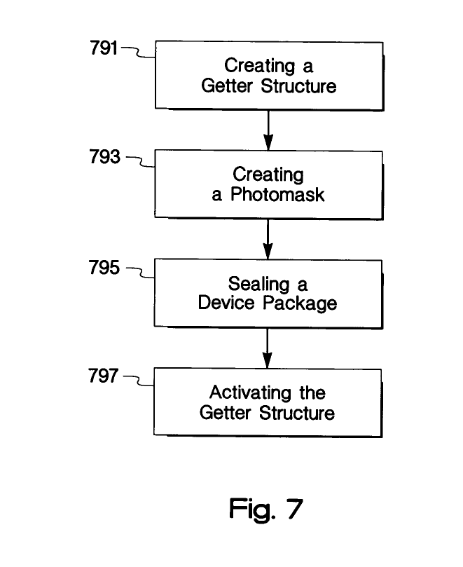

A flow diagram of a method of manufacturing a getter structure enclosed in a device package, according to an embodiment of the present invention, is shown in FIG. 7. Getter structure creating process 791 is utilized to create a getter structure coupled to a substrate or other device component part such as a chip carrier, lid, cover or package base. The particular material utilized will depend on the particular application in which the getter structure is to be used and will depend on various factors such as the species or impurities to be gettered, the environment in which the device will be utilized, the expected lifetime of the device, and any limitations on activation temperatures. For example, in devices utilizing a vacuum environment, Zr—V—Ti alloys, or Zr—V—Fe alloys generally have lower activation temperatures compared to Zr—Al alloys and thus may be utilized in those devices more susceptible to thermal degradation or damage. Examples of other getter materials that also may be utilized in a vacuum environment include titanium, zirconium, thorium, hafnium, vanadium, yttrium, niobium, tantalum, and molybdenum. However, in still other embodiments, any material having sufficient gettering capacity for the particular application in which the getter structure will be utilized also may be used. Generally a getter structure is created utilizing various deposition techniques such as sputter deposition, chemical vapor deposition, evaporation, or other vapor deposition techniques. However, in alternate embodiments, other deposition techniques such as electrodeposition or laser activated deposition also may be utilized. In addition, getter preforms also may be attached or mounted to the substrate or package component. Further, other techniques such as electrophoresis, manual, or mechanical application, including screen printing, inkjet printing, spraying suspensions of the getter material in a suspending medium, also may be utilized to form a wide variety of getter structures using a wide variety of getter materials. The particular deposition technique utilized will depend on the particular material chosen. For those embodiments utilizing a blanket deposition of the material over the substrate, generally, conventional photolithographic and etching techniques may be utilized to form the desired pattern of the getter structure. In addition, a lift-off process also may be utilized where a blanket getter layer or film is deposited over a pre-defined photoresist pattern having re-entry photoresist sidewall profiles in the opening regions of the photoresist. The getter structures are formed when the unwanted getter material deposited on the photoresist is lifted off or removed with the photoresist. Both additive and subtractive processes may be utilized to form the desired pattern of the getter structure.

For those embodiments in which the getter structure is formed on a thermally isolated structure various wet or dry etchants may be utilized along with conventional photolithography techniques. For example, a dry etch may be used when vertical or orthogonal sidewalls are desired. Sacrificial materials also may be deposited on the top and bottom surfaces of the getter structure. The sacrificial materials such as amorphous silicon may be removed selectively by utilizing a xenon difluoride or sulfur hexafluoride plasma etch to create free-standing thermally isolated getter structures. Alternatively an anistropic wet etch such as potassium hyrdoxide (KOH) may be used to etch a (110) oriented silicon wafer to also produce vertical sidewalls. Further, the use of an anisotropic wet etch such as KOH or tetra methyl ammonium hydroxide (TMAH), may be utilized to etch a (100) oriented silicon wafer to produce various structures with sloped side walls generated by the slower etch rate of the (111) crystallographic planes. In still other embodiments, combinations of wet and dry etch may also be utilized when more complex structures are desired. Further, other processes such as laser ablation, reactive ion etching, ion milling including focused ion beam patterning may also be utilized to form a thermally isolating structure.

Photomask creation process 793 is utilized to create or form and mount a photomask to a device package surface. Any of a wide range of techniques may be utilized to create the photomask. For example, the photomask may be desposited on a device package surface such as the back side or second major substrate surface utilizing various deposition techniques such as sputter deposition, chemical vapor deposition, plasma enhanced chemical vapor deposition, evaporation, or other vapor deposition techniques. In addition, other deposition techniques such as electrodeposition, or laser activated deposition also may be utilized. Generally for both metal reflective and quarter wave dielectric reflective masks, as well as antireflective layers any of the deposition techniques utilized to deposit metals or dielectrics may be used. Both additive and subtractive processes may be utilized to form the desired pattern of the mask. For those embodiments utilizing a grating mask the grating material may be deposited on the device package surface and then the grating etched into the surface utilizing conventional patterning and etching techniques. In still other embodiments the grating may be etched into the device package surface directly without an additional deposition step. Besides the more conventional techniques of depositing an inorganic dielectric, noted above, with subsequent patterning; grating masks also may be fabricated by coating or solution casting a polymer such a polycarbonate or polymethylmethacrylate on the device package surface followed by various patterning techniques including micromolding. Another example is where the mask is formed separate as a free-standing mask and then is attached to a device package surface utilizing an adhesive or a mask release layer. In still other embodiments where the photomask is a specified distance away from the device package surface any of the wide variety of techniques used to form and pattern photomasks may be utilized.

Device package sealing process 795 is utilized to seal and enclose the getter structure in a device package. Any of a wide range of techniques may be utilized to seal a device package. For example to bond a silicon die to a ceramic package or metal can a gold-silicon etutectic or a softer lower melting point solder, may be utilized. The particular sealing or bonding material as well as the sealing technique will depend on various factors such as, on the desired pressure to be maintained in the enclose region of the getter, on the temperature and humidity and other environmental factors to which the micro-fabricated device will be exposed, and on the amount of stress that may be imparted to device as a result of the sealing process. Thermal compression bonding, brazing, and anodic bonding, are just a few of the many techniques that may be utilized. A low melting-point inorganic oxide glass such as, lead oxide or boric oxide also may be used to form the bond structures used to generate a sealed package. In still other embodiments, anodic bonding may be utilized to attach a silicon substrate to the sealing plate either made out of glass or having a glass surface to bond to the silicon. The silicon surface of the substrate and, for example, the glass surface of the sealing plate are placed between two electrodes applying an appropriate polarity voltage across the interface of the two materials. A frit glass seal may be utilized to form a sealed package. In addition, various adhesives and adhesive structures also may be utilized.

Getter structure activating process 797 is utilized to activate the getter material and may be any of the processes described above for heating the getter material to its activation temperature.

1. A method of activating a getter structure, comprising:
illuminating a photomask having a transmissive region substantially aligned with the getter structure;
transmitting a portion of said photons through, said transmissive region;
absorbing said photons, transmitted through said transmissive region, in the getter structure; and
heating the getter structure with said absorbed photons.

2. The method in accordance with claim 1, wherein heating the getter structure further comprises heating the getter structure to at least the activation temperature of the getter structure.

3. The method in accordance with claim 1, further comprising positioning said photomask wherein said transmissive region is substantially aligned over said getter structure.

4. The method in accordance with claim 3, wherein positioning said photomask further comprises:
translating said photomask in a first direction; and
translating said photomask in an orthogonal direction to said first direction.

5. The method in accordance with claim 4, further comprising rotating said photomask about a center of rotation.

6. The method in accordance with claim 4, further comprising rotating said photomask in the plane formed by said first and said orthogonal direction.

7. The method in accordance with claim 3, wherein positioning said transmissive region further comprises adjusting said photomask to be a specified distance from said getter structure.

8. The method in accordance with claim 1, wherein illuminating said photomask further comprises illuminating a partially transmissive region formed in said photomask with photons emitted from a photon source and incident on said photomask.

9. The method in accordance with claim 8, wherein illuminating said partially transmissive region further comprises:
transmitting a portion of said photons incident on said partially transmissive region; and
absorbing said portion of said transmitted photons in a specified portion of a substrate or a device package material on which the getter structure is disposed, wherein said specified portion of said substrate or said device package material substantially aligns with said partially transmissive region.

10. The method in accordance with claim 9, further comprising heating said specified portion of said substrate or said device package material.

11. The method in accordance with claim 1, wherein illuminating said photomask further comprises illuminating a grating photomask having at least one transmissive region and at least one non-transmissive grating region.

12. The method in accordance with claim 11, wherein illuminating said grating photomask further comprises illuminating a quarter wavelength grating region disposed on said grating photomask.

13. The method in accordance with claim 11, wherein illuminating said grating photomask further comprises illuminating a grating photomask having at least one partially transmissive grating region disposed on said grating photomask.

14. The method in accordance with claim 1, wherein illuminating said photomask further comprises illuminating a reflective photomask having at least one transmissive region and at least one reflective substantially non-transmissive region.

15. The method in accordance with claim 14, wherein illuminating said reflective photomask further comprises illuminating said reflective photomask having at least one partially reflective region.

16. The method in accordance with claim 1, wherein illuminating said photomask further comprises illuminating an absorptive photomask having at least one transmissive region and at least one absorptive non-transmissive region.

17. The method in accordance with claim 17, wherein illuminating said reflective photomask further comprises illuminating a reflective photomask having at least one partially transmissive absorptive region.

18. The method in accordance with claim 1, wherein illuminating said photomask further comprises illuminating a photomask having:
at least one transmissive region;
at least one non-transmissive region; and
at least one partially transmissive region.

19. The method in accordance with claim 1, wherein illuminating said photomask further comprises illuminating said photomask with photons emitted from a photon source, said photon source emitting photons in substantially the infrared region of the electromagnetic spectrum.

20. The method in accordance with claim 1, wherein transmitting said portion of said photons further comprises transmitting a portion of said photons through a transmissive region formed in a reflective film disposed on said photomask.

21. The method in accordance with claim 20, further comprising transmitting said photons through said transmissive region of said reflective film deposited on a glass or polymer photomask substrate.

22. The method in accordance with claim 1, wherein illuminating said photomask further comprises illuminating said photomask disposed on a device package surface.

23. The method in accordance with claim 22, further comprising removing said photomask from said device package surface.

24. The method in accordance with claim 23, wherein removing said photomask further comprises removing a release layer disposed between said device package surface and said photomask.

25. The method in accordance with claim 22, further comprising illuminating a reflective film disposed on said photomask disposed on said device package surface.

26. The method in accordance with claim 25, further comprising removing said reflective film from said device package surface.

27. The method in accordance with claim 26, wherein removing said reflective film further comprises removing said reflective film disposed on a exterior package surface, wherein said getter structure is disposed on an opposing interior package surface.

28. The method in accordance with claim 26, wherein removing said reflective film further comprises chemically etching said reflective film.

29. The method in accordance with claim 26, wherein removing said reflective film further comprises removing a release layer disposed between said device package surface and said reflective film.

30. The method in accordance with claim 22, wherein illuminating said photomask further comprises illuminating a grating photomask disposed on said device package surface.

31. The method in accordance with claim 30, wherein illuminating said grating photomask further comprises:
illuminating at least one substantially transmissive region; and
illuminating at least one substantially non-transmissive region.

32. The method in accordance with claim 30, wherein illuminating said at least one substantially non-transmissive region further comprises illuminating a quarter wavelength grating.

33. The method in accordance with claim 30, further comprising illuminating at least one partially transmissive region.

34. The method in accordance with claim 33, wherein illuminating said at least one partially transmissive region further comprises illuminating at least one partially transmissive region that transmits in the range from about 10 percent to about 90 percent of the photons impinging upon said partially transmissive region.

35. The method in accordance with claim 1, wherein illuminating said photomask further comprises illuminating a grating or a reflective photomask.

36. The method in accordance with claim 1, wherein absorbing said photons, further comprises absorbing said photons transmitted through said transmissive region in said photomask and transmitted through a substrate forming a portion of a device package, wherein the getter structure is disposed on an interior surface of said device package.

37. The method in accordance with claim 1, wherein heating the getter structure further comprises heating the getter structure disposed on an interior surface of a device substrate, said device substrate forms a portion of a package enclosing the getter structure.

38. The method in accordance with claim 1, wherein heating the getter structure further comprises heating the getter structure enclosed within a device package.

39. The method in accordance with claim 1, wherein heating the getter structure further comprises heating the getter structure having a suspended mass portion suspended over a cavity formed in a device substrate.

40. The method in accordance with claim 1, wherein heating the getter structure further comprises heating the getter structure having a free standing portion and at least one additional getter layer disposed over and separated by a gap from said free standing portion, said free standing portion suspended over a cavity formed in a substrate.

41. The method in accordance with claim 1, wherein heating the getter structure further comprises heating the getter structure having an absorption layer disposed between the getter structure and a substrate or device package material.

42. The method in accordance with claim 1, wherein heating the getter structure further comprises heating the getter structure disposed on a substrate or device package part, wherein said substrate or device package part includes a trench formed in said substrate or device package part and said trench encircles the getter structure.

43. The method in accordance with claim 1, further comprising reactivating the getter structure at a specified pressure.

44. The method in accordance with claim 1, further comprising reactivating the getter structure after a specified time.

45. The method in accordance with claim 1, wherein transmitting said portion of said photons further comprises transmitting said portion of said photons through said substrate.

46. A method of making a device, comprising:
creating a getter structure on a substrate or a device component part of a device package;
creating a photomask on a surface of either said substrate or of said device component part; and
activating said getter structure by the method of claim 1.

47. The method in accordance with claim 46, further comprising sealing said device package.

48. The method in accordance with claim 46, wherein creating said getter structure further comprises creating a getter structure utilizing a material selected from the group consisting of Zr—V—Ti alloys, Zr—V—Fe alloys, Zr—Al alloys and mixtures thereof.

49. The method in accordance with claim 46, wherein creating said getter structure further comprises creating a getter structure utilizing a material selected from the group consisting of zirconium, thorium, hafnium, vanadium, yttrium, niobium, tantalum, molybdenum, terbium, and mixtures thereof.

50. The method in accordance with claim 46, wherein creating said getter structure further comprises creating a thermally isolated getter structure.

51. The method in accordance with claim 46, wherein creating said getter structure further comprises creating a getter structure having a suspended mass portion suspended over a cavity formed in said substrate or in said device component part.

52. The method in accordance with claim 46, wherein creating said getter structure further comprises creating a getter structure having a free standing portion and a second getter layer disposed over and separated by a gap from said free standing portion, said free standing portion suspended over a cavity formed formed in said substrate or in said device component part.

53. The method in accordance with claim 46, wherein creating said getter structure further comprises creating a getter structure having an absorption layer disposed between said getter structure and said substrate or said device component part.

54. The method in accordance with claim 46, wherein creating said getter structure further comprises creating a getter structure disposed said substrate or said device component part, wherein said substrate or said device component part includes a trench formed therein, and said trench encircles the getter structure.

55. The method in accordance with claim 46, wherein creating said getter structure further comprises forming said getter structure by ink-jet deposition.

56. The method in accordance with claim 46, wherein creating said photomask further comprises creating a reflective photomask.

57. The method in accordance with claim 46, wherein creating said photomask further comprises creating a quarter wavelength grating photomask.

58. The method in accordance with claim 46, wherein creating said photomask further comprises creating an absorptive photomask.

59. The method in accordance with claim 46, wherein creating said photomask further comprises micromolding said photomask.

60. The method in accordance with claim 59, further comprising attaching said photomask to said surface of either said substrate or of said device component part.

61. The method in accordance with claim 46, wherein creating said photomask further comprises creating a photomask having transmissive and non-transmissive regions.

62. The method in accordance with claim 46, wherein creating said photomask further comprises creating a photomask having transmissive, non-transmissive regions and partially transmissive regions.

63. The method in accordance with claim 46, wherein creating said photomask further comprises etching a photomask on said surface of either said substrate or of said device component part.

64. The method in accordance with claim 46, wherein creating said photomask further comprises coating or solution casting a polymer on said surface of either said substrate or of said device component part.

65. The method in accordance with claim 46, wherein activating said getter structure further comprises illuminating a photomask having:
at least one transmissive region;
at least one non-transmissive region; and
at least one partially transmissive region.

66. A method of activating a getter structure disposed in a device, comprising:
illuminating a vacuum device with photons emitted from a photon source, said vacuum device having the getter structure disposed over a substrate;
transmitting a portion of said photons through a transmissive region substantially aligned with the getter structure, said transmissive region formed in a photomask disposed between the getter structure and said photon source; and
heating the getter structure above its activation temperature.

67. A method of activating a getter structure disposed in a device, comprising:
uniformly illuminating the device with photons emitted from a photon source, wherein the getter structure is disposed over or on a substrate forming a portion of the device;
transmitting a portion of said photons through a transmissive region formed in a photomask, said transmissive region substantially aligned with the getter structure;
heating the getter structure above the activation temperature of the getter structure with absorbed photons.

68. The method in accordance with claim 67, further comprising positioning said transmissive region over the getter structure.

69. The method in accordance with claim 68, wherein positioning said transmissvie region further comprises:
translating said photomask in a first direction;
translating said photomask in an orthogonal direction to said first direction;
rotating said photomask about a center of rotation.

70. The method in accordance with claim 67, wherein illuminating the device further comprises illuminating a grating photomask having at least one transmissive region and at least one non-transmissive region.

71. The method in accordance with claim 70, wherein illuminating said grating photomask further comprises illuminating at least one partially transmissive grating region disposed on said grating photomask.

72. The method in accordance with claim 67, wherein illuminating the device further comprises illuminating a reflective photomask having at least one transmissive region and at least one non-transmissive reflective region.

73. The method in accordance with claim 70, wherein illuminating said reflective photomask further comprises illuminating at least one partially reflective transmissive region disposed on said reflective photomask.

74. The method in accordance with claim 67, wherein transmitting said portion of said photons further comprises transmitting a portion of said photons through said transmissive region formed in said photomask disposed on the device.

75. The method in accordance with claim 74, further comprising removing said photomask from the device.

76. The method in accordance with claim 67, wherein illuminating said device further comprises illuminating a device having a getter structure disposed over a silicon substrate.

77. The method in accordance with claim 76, further comprising illuminating said getter structure through said silicon substrate.

78. The method in accordance with claim 67, further comprising transmitting a portion said photons through said substrate.
